(19) United States
(12) Patent Application Publication
(10) Pub. No.: US 2007/0290704 A1
(43) Pub. Date: Dec. 20, 2007

(54) Method and circuit for adjusting characteristics of packaged device without requiring dedicated pads/pins

(75) Inventors: Ong Lee Shyh, Bayan Lepas (MY); Wilfred King Wee Kee, Kuching (MY); Goh Fah Liang, Kuching (MY); Lester Cheung Ted Kong, Kuching (MY); Andrew Chien Kai Bing, Kuching (MY)

Correspondence Address: Bo-In Lin, 13445 Mandoli Drive, Los Altos Hills, CA, 94022, US

(73) Assignee: Blessed Electronics Sdn. Bhd. (712261-V)

(21) Appl. No.: 11/454,317

(22) Filed: Jun. 16, 2006

(51) Int. Cl. G01R 31/02; G01R 31/28

(52) U.S. Cl. 324/763; 324/158.1

(57) ABSTRACT

A method and circuit for adjusting packaged device output characteristics without dedicated pads or pins are disclosed. As opposed to multiple bit selection for the purpose of trimming, the method utilizes an iterative and dynamic means to trim the bits of a built-in trimming network such as an impedance network one bit at a time. Trim time will be short because each single loop trim cycle is very short. The method is robust and not overly complicated thus may be implemented very practically. The system is dynamic in nature because the operation of the device to be trimmed need not be changed from one mode to another.

### BACKGROUND OF THE INVENTION

1. Field of the Invention

This invention relates generally to device configurations and processes for manufacturing electronic devices. More particularly, this invention relates to a method and system for trimming and adjustment of specific characteristics of devices including integrated circuits after the packaging process of such devices are completed without requiring dedicated pads or pins.

2. Description of the Related Art

The processes of manufacturing and packaging an electronic devices are still challenged by a technical difficulty arising from the circuit trimming requirements both at the wafer level and also after the completion of the packaging processes. The trimming processes according to conventional technologies often increase the production costs due to a requirement of significantly increasing the die size. The trimming processes further delay the product to market times, and may also reduce the product reliability due to the application of more complicated trimming processes. Adjustments of circuit parameters by applying the circuit trimming processes are required due to the high probability of variances and deviations of device performance parameters from the required specification of an integrated circuit. In manufacturing and packaging an electronic device, there are multiple processing steps. Variance from the product specification may arise from manufacturing process shifts, defects, design uncertainties, package level shifts and a multitude of other controllable or uncontrollable environment changes that may occur during the entire manufacturing and packaging processes. In order to correct these variances and deviations, flexibilities must be provided to nodes in the circuitry of an integrated circuit for circuit adjustments to achieve tighter tolerances or correct the deviations. The trimming and adjustment processes may cover a wide variety of device parameters, including offset, dropout, gain, drift, frequency, duty cycle and a plurality of other parameters depending on the critical parameters required by the output of the integrated circuit. The final trimming and adjustment processes may also be feasible to facilitate the design and manufacture of generic target devices. A finalization of the required product with options to meet finalized specification may be performed after a batch fabrication and packaging process are completed. Specifically, the methods of trimming and adjustment may include laser trimming, zener zaps or antifuse, fuse or link burning, and memory ROMs such as EPROM.

A laser trimming technique generally refers to the method used to burn or modify specific nodes typically implemented as resistors for the purpose of adjusting the value of a resistance ladder or network. The process is performed with a laser beam focused on a localised node to generate heat at the node. The heat thus modifies the characteristics of thin film material that either completely burns out the material or otherwise changes the width of the resistive material and thereby changing the resistance. A laser trimming process requires expensive equipment and may only be implemented at wafer level thus is unable to correct variances or deviations resulting from the packaging operations of the integrated circuits. The laser trimming therefore has only limited applications.

The fuse burning or link burning process generally refers to the method used to sever a node in the circuitry, typically to modify the resistance in a resistive ladder or network. Instead of applying the laser beam, a high current is injected into the node to break the connection of a resistive element, typically networked within the system. This method is traditionally employed at wafer level. Generally the connecting pads that are not used for bonding at package level are utilized as trim pads. The trimming procedure is controlled through selectively trimming these trim pads. Because the fuse burning or link burning process is carried out at the wafer level, additional package level pins must be introduced to further correct the device variances introduced during the packaging processes. Additional pins lead to larger die size and increase the package pin count.

A Zener zap or anti-fuse process performs similar functions as that carried out in the processes of fuse burning described above. Instead of severing the connection of the parallel resistor, the Zener zaps or anti-fuse process creates connection through applying a high voltage to the anti-fuse to induce avalanche breakdown across a base-emitter junction. The avalanche breakdown generates rapid metal/conductive migration thus causing a metallurgical short across the junction. Similar to the fuse burning or link burning processes, application of the Zener zaps or anti-fuse process also requires either the trim pads and/or additional package pins to achieve necessary correction of manufacturing variances depending on whether the Zener zap process is implemented at wafer or package level.

More recent trimming schemes utilize some form of memory in order to store trim data. After determining the required trimming of the device, the information related to the trimming operation is stored in the memory and the data is transferred to a programming cell in order to manipulate the trimming of the device. By applying this procedure, reprogramming the system by using the data stored in the memory to iterate the trimming process for achieving better trimming accuracy is feasible. However, this process requires at least one additional pin for data communication to and/or from the memory. Furthermore, such a scheme typically utilizes a larger die area due to the size of the memory required and the internal programming cell utilized.

In an US patent entitled “Post-package Trimming of Analog Integrated Circuits” (U.S. Pat. No. 6,621,284 B2) issued on Sep. 16, 2003 assigned to Advanced Analogic Technologies, Inc., a trimming method is introduced by applying a test mode circuit to determine and establish a test mode operation of the analog IC. A register control circuit generates data signals and a plurality of control signals. Another register circuit receives the data signals as directed and generates a plurality of trim control signals based on the states of the storage device. Meanwhile, a trim control circuit applies the trim control signals to modify a normal operation of the packaged analog IC. In test mode, pin functions are redefined and used to enter trim data into an internal input shift register of the linear regulator. A program sense circuit coupled to the register circuit is configured to sense a program voltage. The program enable signal is passed along with the control signal to register circuit to indicate when programming should occur.

Indicative of this invention is its complexity in achieving a post package trimming process and the reuse of pins. It requires a circuit to generate a test mode input circuit that is distinctively separate from the normal operation of the device to be trimmed. The advantage of employing such a scheme is seen in its exemplary embodiment. Because the normal operation of the device to be trimmed is effectively shutdown, the output pins of the device are available for inputting data signal into the circuit. However, with a method that is dependent on requiring different modes of operation and the normal mode of operation is non-functional during the test mode, runs the risk of conflict should the normal mode of operation is not fully shutdown during the test mode. Trimming time would also increase due to the requirements to switch between modes of operation during batch trimming.

A more dynamic trimming method was introduced in another US patent entitled “Method and Circuit for Improving Control of Trimming Procedure” (U.S. Pat. No. 6,927,624 B2) issued on Aug. 9, 2005 assigned to Texas Instruments Incorporated. The trimming control of this patented invention utilized the ohmic relationship existing in the output pin or the pin to be trimmed. Dynamic monitoring of current was complimented with dynamic control of voltage. Since the control of voltage does not affect the current output, voltage was used as a control signal that is fed back into the integrated circuit through the same output pin. Conversely this process can also be applied when a trimming operation is applied to correct the variances in voltage. However, the trimming process encounters its limitation when a trimming process is required to adjust both the voltage and the current. Due to the interdependent relationship between these two parameters in an electronic device, a different method must be implemented when both parameters must be adjusted.

Another US patent entitled “System and Method for Trimming IC Parameters” (U.S. Pat. No. 6,338,032 B1 issued on Jan. 8, 2002 assigned to Analog Devices, Inc.,) claims a trimming system where Trim signals affecting various IC parameters are generated in response to digital bit patterns, in conjunction with respective digital-to-analog converters (DACs). Bit patterns are created iteratively until an acceptable range for the determined parameter is identified. This bit pattern can then be permanently encoded through more permanent trimming means. A switching network is provided to allow inaccessible internal nodes to be accessible via I/O pins for measurement purposes. The trimming circuit is packaged in an IC package and is operable via I/O pins, thus allowing post-assembly trimming. However, compared to the other two methods, this method does not consider reuse of pins and thus will add to the pin count of the final packaged device when post-assembly trimming is employed. Furthermore, the idea of previewing device characteristic data prior to trimming, although ideal, is time consuming and will only add cost to the trimming process. Such a scheme will only be valid when extremely tight tolerance and accuracy is required of the device to be trimmed.

Therefore, a need still exists in the art for a method and system for adjusting specific nodes of a semiconductor chip or device without requiring additional package pins thus avoid the disadvantages of uneconomically increasing the die size. It is further desirable to avoid the requirement of expensive testing and trimming equipment. Furthermore, the new and improved method and system should be capable of adjusting the nodes after packaging to account for potential operating shifts due to package level processing. It is further desirable that the test and trimming processes should be dynamic in nature in order to save trim time and not be overly complex as to jeopardize the trimming process. The system should ideally be robust, and thus not restricted by sensitivity limitations when applied in wide variety of test and trimming conditions. It is further desirable that the new and improved methods as disclosed in this invention may allow wafer level testing to be skipped should the production yield at the wafer level exceeds an acceptable threshold value.

### SUMMARY OF THE PRESENT INVENTION

It is a general aspect of the present invention to provide a method and circuit for adjusting the characteristic of a target semiconductor device without requiring additional pins or bond pads dedicated for the purpose in order to substantially obviate one or more problems caused by the limitations and disadvantages of the related art discussed above.

Another aspect of this invention is the trimming method involves the reuse of existing pins of a semiconductor device for adjusting at least one critical parameter that requires trimming to achieve acceptable target values within a required specification. Moreover, the method is dynamic. The trimming and measurement of output characteristic parameters are carried out in real time. Therefore, the process of trimming for adjusting the circuit characteristic is performed without requiring a transition between different modes of operation. In an exemplary embodiment, the trimming process is performed when device is operated under similar conditions as its normal operation and the output from the output pin may be used as a reference measurement to monitor the operation between trimming and the changes of the output measurements.

In a preferred embodiment, the invention utilizes the enable pin and the bypass pin that are provided for a device for trimming in order to generate the required signals and operation of the trimming sequence. The advantage of such device configuration is to avoid the requirements of increasing the die size and reduce cost of trimming because of the exclusion of trim pads required for wafer level fuse or zener zapping operations, the exclusion of expensive equipment required by laser trimming processes and furthermore avoid the increase in package pin count due to the requirement of package pins exclusive to the trimming procedure. Use of this method that is performed after the completion of a packaging process will also allow for compensation of packaging shifts. In its exemplary embodiment, the invention avoids increase in package pin count through the reuse of the bypass and enable pin available on the packaged device. The trimming operations of the invention after the packaging process are more robust, practical and time saving and further allows for simultaneous adjustment of current and voltage or other function interdependent operation parameters. It is further possible to extend the method to compensate for other characteristics of the output signal such as frequency and phase.

In a preferred embodiment, the circuit arrangement of the trimming system includes a counter circuit with a number of bits corresponding to a required number of bits of a trimming impedance network and further corresponding to the number of parameters required to be trimmed. The impedance network are provided according to the parameters to be trimmed and may preferably include a network of resistive, capacitive and inductive elements, although in its preferred embodiment, a resistive network is exemplified.

By fuse burning a corresponding bit in the impedance network, the parameter to be trimmed may be adjusted accordingly. This process may be repeated in order to fine tuning the parameter to be trimmed. The accuracy and precision and fineness of the trimming operation are determined by the size of the impedance network. The area that would be taken up by the impedance network in the die area of the device to be trimmed further determines the implementation of the resistive network and the configuration. The bits of the counter are predetermined to correspond to adjustments on a particular value of the parameters to be trimmed. The bit for trimming is sequentially loaded into a counter during the trimming process. By sequentially loading the trimming parameters progressively, it is possible to achieve a series of possible trim value adjustments. In a preferred embodiment, the counter is reset and sequentially loaded by means of the bypass and enable pin of the device to be trimmed.

In a preferred embodiment, an interface circuit coupled between the bypass pin and the trimming circuitry is implemented in order to avoid noise affecting the trimming scheme. The interface circuit may be implemented as an analog interface circuitry. The purpose of the interface circuit is to differentiate between the actual signal injected into the pin and noise signals generated from ambient background or alternative sources. In a preferred embodiment, the signal injected into the enable pin for the purpose of trimming may be implemented as a clock to serially shift the counter circuit whereas the signal injected through the bypass pin is used first to enable the trimming process. Then the signal is used to reset the counter circuitry. After the counter circuitry is reset, the signal is used to provide the fuse-burning signal under a specified and predefined condition.

The requirement and determination of the required trim value is based on the trim circuitry external to the device to be trimmed. It is also feasible for any number of the external blocks to be integrated into the device to be trimmed at the expense of die area. A reference value is compared to the output or outputs of the device to be trimmed. The variation between the reference parameter characteristic and the characteristic of the parameter to be trimmed is determined. The value to be trimmed is specified by the tolerance allowed by the device to be trimmed compared against the target parameter value. This tolerance value is adjustable when the circuit is external to the device to be trimmed. In a preferred embodiment, an external system detects a specific combination of system conditions that indicates the trimming sequence is in progress. This combination of system conditions include the output of the device to be trimmed is pulled high corresponding to the input voltage of the device to be trimmed. This condition occurs when the bypass pin of the device to be trimmed is correspondingly pulled high via signal injected into the bypass pin. This combination of system conditions only occurs when trimming is in progress. A final trimming fuse is used to disable further adjustments to the device once acceptable target values of the output or outputs are achieved.

This invention is robust and may be used to trim a plurality of required parameters to meet required specification of the device to be trimmed. Parameters such as voltage, current, amplitude, phase and frequency may be trimmed accordingly with respect to their respective impedance networks in order to achieve defined tolerance requirements. It is also possible to use this trim method to trim specific target options in a device to be trimmed. It is further possible to use this trim method in order to change the polarity of logic functionality in a system such as negative enable or positive enable of the device to be trimmed.

### BRIEF DESCRIPTION OF THE DRAWINGS

A deeper and thorough understanding of the present invention may be derived from the reference of the detailed description and claims when considered along with the Figures presented, where same reference numbers refer to similar elements throughout the Figures, and:

FIG. 1 illustrates a functional block diagram of an exemplary circuit for illustrating the implementation of a trimming circuit shown in FIG. 2 to more accurately and conveniently adjust the output parameters from the circuit.

FIG. 2 illustrates an exemplary circuit for an impedance network included in a circuit of FIG. 1 to achieve more convenient and more precise circuit trimming without requiring dedicated pads and pins.

FIG. 3 illustrates a block diagram of an exemplary system level circuit for improved control and implementation of the trimming procedure in the device shown in FIG. 1 in accordance with an exemplary embodiment of the present invention.

FIG. 4 illustrates a block diagram of an exemplary circuit for control and drive of the trimming control system exemplified in the system level circuit of FIG. 3.

FIG. 5 illustrates an exemplary method for control of the trimming procedure of a device to be trimmed in accordance with an exemplary embodiment of the present invention.

### DETAILED DESCRIPTION OF THE PREFERRED EMBODIMENTS

Before disclosing the preferred embodiments of the present invention, it is understood that the invention is not limited to the application and to the details of the particular arrangement described and shown, as the invention is capable of alternative embodiments. It should also be appreciated that although various components may have been suitably coupled or connected to other components within the exemplary embodiments, the connections and couplings may be realized either by direct connection between said components or via connections through other components and devices located between described components. Furthermore, the terminology used herein is for the purpose of description and therefore not limiting to the scope of the invention.

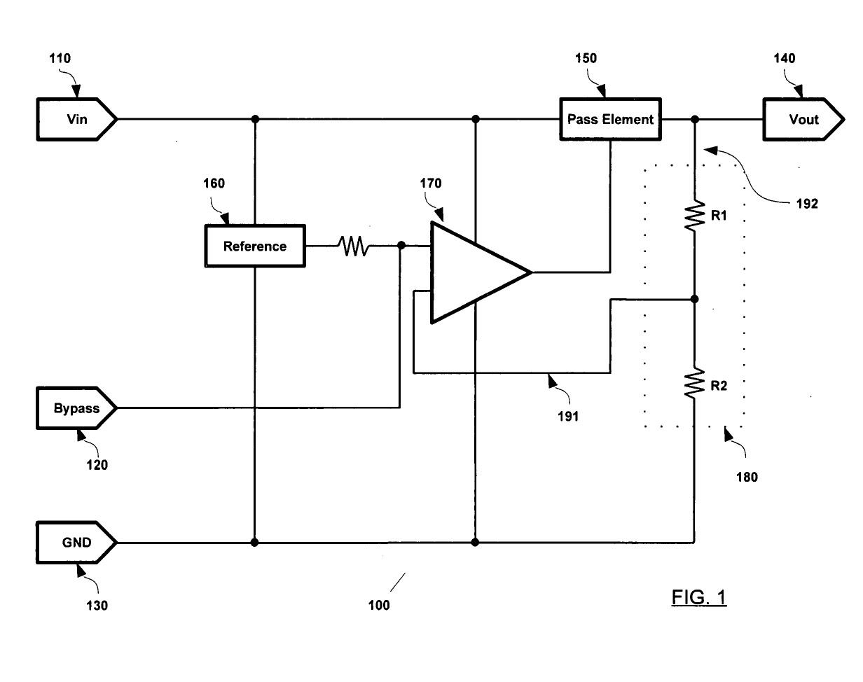

In accordance with the various aspects of the present invention, a method and circuit is provided for improving the trimming methodology in order to adjust packaged device or circuit characteristics without dedicated pads/pins. FIG. 1 shows a block diagram of an exemplary circuit for carrying out a trimming operation in order to obtain a more accurate or precise parameter from its output. In this exemplary embodiment, the circuit block diagram represents a linear low dropout regulator. The regulator includes three input pins and one output pin. The three input pins includes a Vin pin 110 as an input pin to supply an input voltage to the circuit, a GND pin 130 as an input pin to provide a reference ground voltage, and a Bypass pin 120 as input pin to provide a bypass circuit branch for the circuit. The output pin 140 shown as Vout is employed to provide an output voltage generated from the circuit. The voltage applied to the input pin Vin 110 is unregulated and is coupled to a pass element 150. In this exemplary embodiment of the low dropout regulator, the pass element 150 typically comprises a p-type MOSFET. The unregulated voltage supplied by the input pin Vin 110 is coupled to the source and body of the MOSFET shown as the pass element 150 whereas the drain of the MOSFET device is coupled to the output pin Vout 140 and to the impedance network 180.

The impedance network 180 is coupled to the output line through a connector 192. This impedance network provides the means to adjust the output provided by Vout pin 140 through the ratio of R1 and R2 of the impedance network 180 and through the feedback line 191. The feedback line 191 is connected between a point between R1 and R2 and an input to a voltage error amplifier 170. The other input of the voltage error amplifier 170, is tied to a reference voltage supplied by an internal reference 160 that is typically supplied by a band-gap circuit. The configuration as shown operates in a manner such that the error amplifier 170 is implemented to constantly adjust its output so that two input voltages to the error amplifier 170 are equal. This feedback loop provides a function to hold the regulated output at the output pin Vout 140 at a fixed value that is a multiple of the reference voltage supplied by the reference 160 regardless of changes in the load current.

Therefore, according to a circuit configuration as shown in FIG. 1, the output voltage generated and outputted from the output pin 140 may be adjusted. Specifically, the output voltage adjustment is accomplished by adjusting the operation of the control loop of the low dropout regulator through adjusting the ratio of R1 and R2 of the impedance network 180.

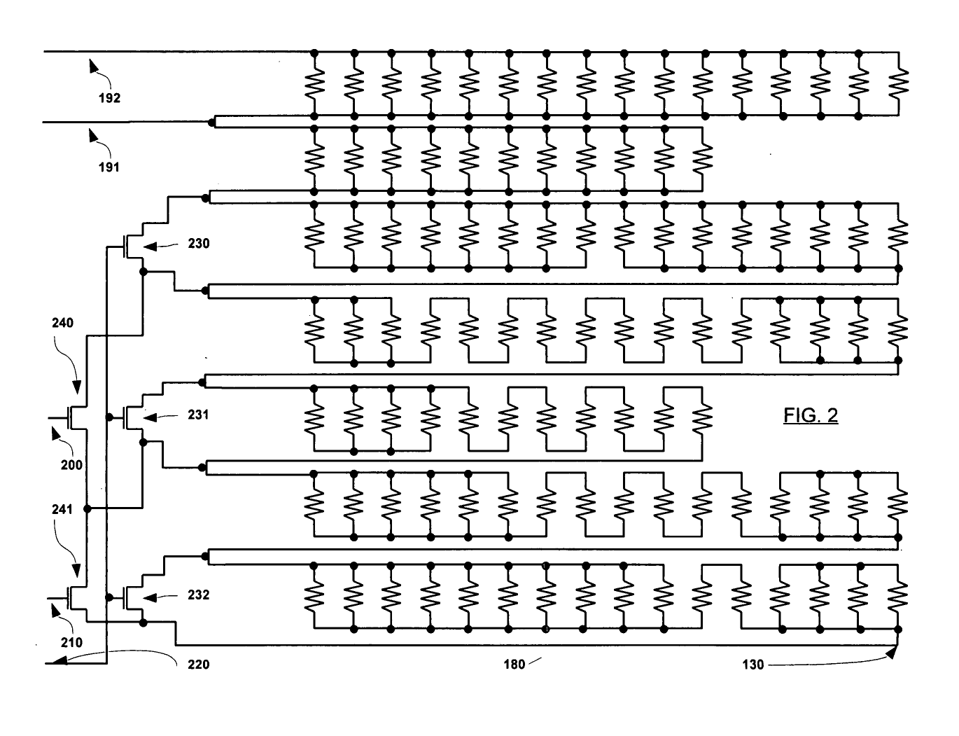

As shown in FIG. 1, the impedance network 180 of the low dropout regulator is implemented with a resistive network R1 and R2. An exemplary embodiment of the resistive network is shown in FIG. 2. It should be clearly understood by those of ordinary skill in the art that the impedance network 180 might be implemented with different circuit elements depending on the trimming requirements of the impedance network for adjusting the operational and output parameters. For example, should there are requirements to adjust either phase or frequency of the output by applying the circuit trimming operations, the impedance network 180 may include capacitive and inductive elements. Therefore, the circuit elements to allow for circuit characteristic parameter adjustments are built in corresponding to circuit parameters adjustment requirements. Therefore, one aspect of this invention is to provide circuit elements ready for specific types of trimming operations to allow for particular types of circuit characteristic parameter adjustments.

Referring to FIG. 2 for an impedance network that allows a 3-bit trimming operation. It may be concluded from the figures and the detailed description of FIG. 2, impedance network 180 may be extended and implemented to allow for additional bit of trimmings. Furthermore, the network may be extended in such a way as to allow for different trimming operations for adjusting different circuit characteristics. Furthermore, the network may be extended to allow for different outputs should a requirement to trim the network to change different network parameters in order to adjust a plurality of outputs corresponding to different trimming network parameters. The exemplary impedance network may be further extended to a plurality of required bits depending on the required number of nodes to be trimmed, the number of features to be trimmed and the accuracy and precision of the trimming.

FIG. 2 shows an exemplary embodiment of a impedance network 180 provided for applying a trimming operation to adjust the output voltage after the device manufacturing processes at a wafer level and the packaging processes are completed. The resistor R1 included in FIG. 1 is shown as a row of parallel resistors coupled between the coupling line 192 and line 192. The coupling line 192 is the connector coupling the impedance network to the output of the pass element 150 and Vout, 140. The coupling line 191, as that shown in FIG. 1 is the feedback line connected to the error amplifier, 170. The resistor R2 is shown to be a network of parallel and series resistors coupled between coupling line 191, and 130, the ground reference line. The sets of parallel and series resistors are coupled to the respective source and drains of a corresponding network of switches, in this case transistors 230, 231, 232, 240 and 241.

By configuring the resistor network 180 as shown in FIG. 2, a first set of transistors, 230, 231 and 232 have their gates tied together thus constitute a selection bit 220 of the trimming network. When this selection bit, 220, is enabled or disabled, the trimming network is switched between two different resistive curves. In this resistive network, only the lower resistive elements, R2, are trimmed. This effectively creates a nonlinear trim curve when attempting to modify the impedance ratio. Thus by introducing a selection bit, it is feasible to modify the impedance curve pattern closer to a linear form. The second set of transistors 240 and 241 has their source and drains coupled to each other as shown in FIG. 2 and are further coupled to the first set of transistors. The gates of the second set of transistors correspond to the number of bits of the trimming network 200 and 210 with the exception of the final bit 220. It can thus be concluded from figures and detailed description thus far that should a particular bit be disabled, through the disabling of its gates 200 and 210, it would be possible to disable the corresponding set of resistive network coupled to that transistors 240 and 241, thereby modifying the ratio of the R1 and R2 resistors embodied in FIG. 1 as representative of an impedance network 180. By this operation, the flexibilities are provided to adjust a specified output parameter of a circuit through modification of the ratio of its impedance network 180. A bit described here is defined as a control signal logic that may be on or off thus determining whether a particular strain of impedance line is included in the adjustment of the output values. A bit on or off may be applied by a control circuit to bypass or short out a particular strain of resistive networks. Different combinations of logic bit would provide a corresponding different value of resistance and the number of combinations may be reflective of a power of two. The final bit line however controls the switching between, effectively, two alternative sub-networks in the impedance network. The reason is because the resistance curve achievable through various combinations in this case is not linear in nature. So in order to achieve a more linearized trimming, an additional curve for impedance is provided. Increasing the number of alternative sub-networks, representative of a change in impedance values would increase linearity but would also, increase complexity and die area size. Increasing the number of sub-networks doesn't change the number of combinations available, but it does mean that the entire network has an increased size since more resistors are now added. Single network, and no sub-network of an 8 bit system provides 2̂8=256 bits of possible adjustable impedance values. With two sub-network of an 8 bit system also provides 256 possible adjustable values, i.e., 2̂7+2̂7=256. With four sub-networks of an 8 bit system, since adding bits to control sub-networks results in binary valued figures that is 2̂6+2̂6+2̂6+2̂6+=256.

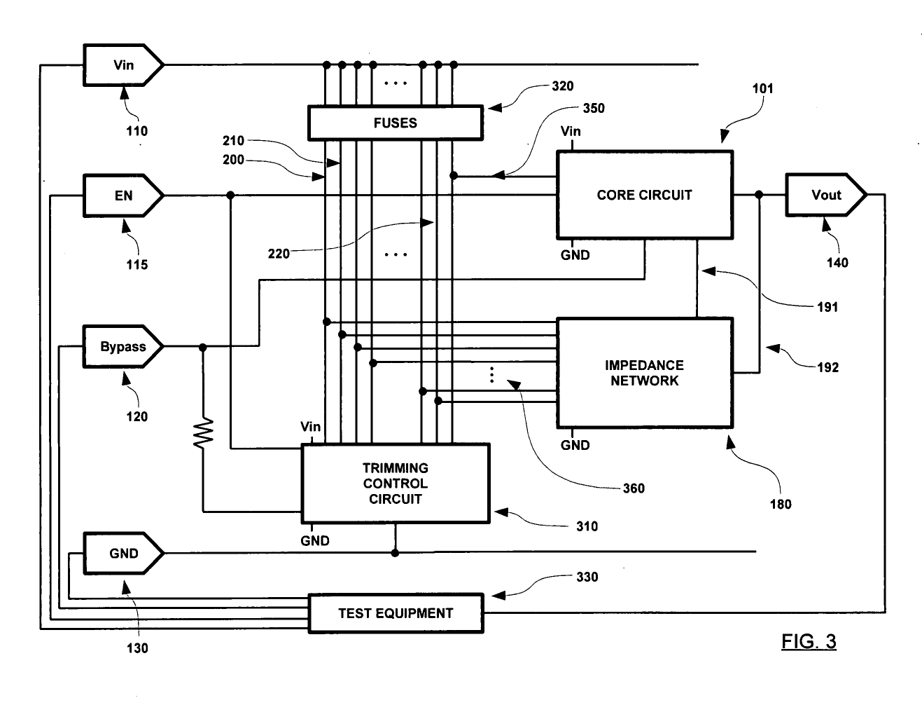

FIG. 3 shows a block diagram of a system to improve the control and implementation of the trimming procedure on the device shown in FIG. 1. The core circuit 101 represents a device to be trimmed that is coupled to the impedance network 180 via the coupling line 191. As shown in FIG. 1, the low-dropout regulator as now represented by the core circuit 101 includes the reference block 160, the pass element block 150, and the error amplifier 170. The core circuit 101 may further include additional blocks for added features, such as but not limited to over-temperature circuits and over-current circuits. It is understood that when the core circuit 101 includes added circuit elements than what is shown in the low-dropout regulator, then the impedance network 180 would include additional trimming circuits to allow for adjustment of the required output parameters through the trimming operations of the impedance network 180.

The impedance network 180 is further coupled to the trimming control circuit 310 and corresponding fuses 320 via coupling lines 360. These coupling lines 360 are tied to the same nodes as the coupling lines 200, 210 and 220 for coupling the trimming control circuit 310 to a network of corresponding fuses 320 according to a configuration as shown in FIG. 2 to carry out the trimming operations for corresponding number of bits through the coupling lines 200, 210 and 220 to disable the corresponding switches or gates or the transistors shown in FIG. 2. It is understood the operations or connections to disable different switches or gates of transistor may also be implemented with anti-fuses or Zener zaps or memory as alternate embodiments.

The trimming control circuit 310 depicted in FIG. 3 selects the appropriate fuse in the fuse box 320. By injecting a high current into corresponding nodes generates a high temperature to burn the selected fuses thus destroying the connections of a resistive element. Typically, the resistive element is networked in the system.

An additional input line EN input pin 115 is included in the embodiment to receive an enabling signal. The EN input pin 115 is coupled to the core circuit 101 to enable the operation of the core circuit. The high and low of the core circuit 101 depends on whether it is negative enabled or positive enabled and is typically dependent on a higher level system requirements.

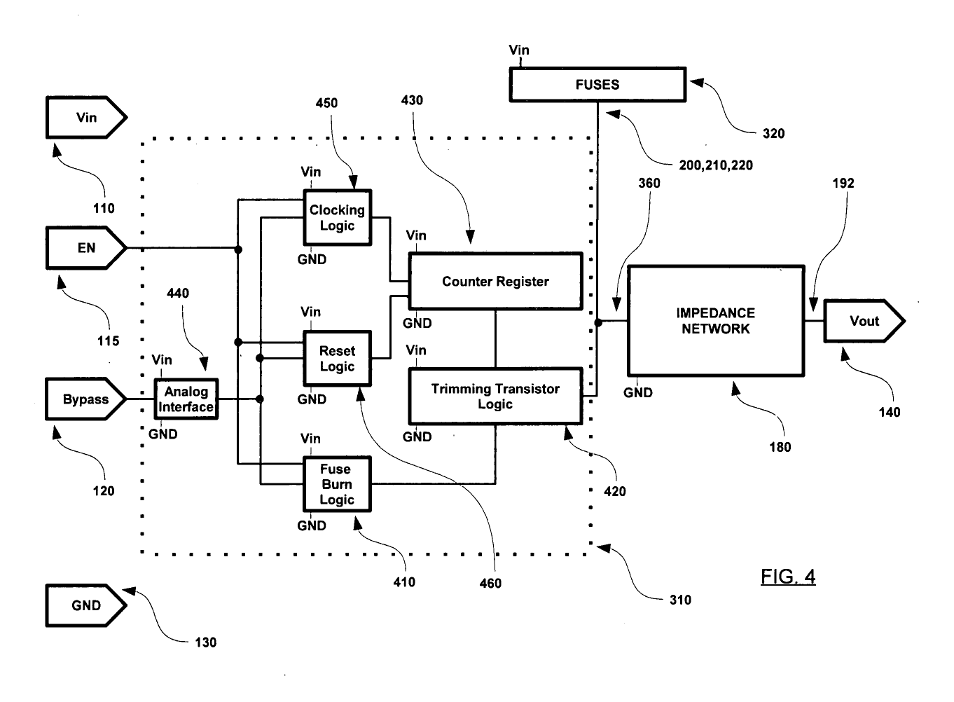

The test equipment, 330 is coupled to the inputs and outputs of the device under the trimming operation including the core circuit 101. The test equipment 330 supplies the required input signals into each corresponding input pin. The test equipment 330 then monitors the output or outputs of the device generated from the trimmed circuit. The test equipment 330 also determines the required trim value performed in the trimming operation. The test equipment 310 is typically implemented as an external and separate circuit from the circuit under the trimming. It is also feasible to integrate the test equipment circuit 310 as a circuit block included as part of the trimming device, however, this integrated configuration may occupy extra die areas thus adversely affect the production cost of the device. The test equipment 330 further provides an internal reference value to compare with the output or outputs of the device under trimming operation. The test equipment 330 further determines the difference between the reference value of the output parameter or parameters with the parameter(s) received from the output pin. The test equipment 310 further compares the difference between the reference value as a target trimming value and the actual output parameter to an output tolerance value. The tolerance value may be an adjustable tolerance value. In an exemplary operation, when a trimming operation is in progress, the output pin Vout 140 is pulled high corresponding to the input voltage Vin 110. And, the bypass pin 120 is correspondingly pulled high also via a signal input into the bypass pin under the condition when the trimming operation is in progress. The bypass pin in its normal operation is typically a pin used to filter out noise of the internal node. In this embodiment, the noise filter is provided attaching a capacitor at the pin to the ground to filter the noise signals generated by a band-gap circuit. But during the trimming state, the bypass pin is used to enable the trimming process by injecting a input high signal into the pin. Normally, in the case of the LDO, the voltage at the node that is connected to the bypass pin is a bandgap voltage value of 1.2V. But the signal injected through the bypass pin is a signal of logic high, typically Vcc, 3.3V —hence pulled high. When this occurs, the trimming circuit that is connected also to the bypass pin is also enabled via the comparator in the analog interface circuit as that depicted in FIG. 4. Another effect of injecting a high signal into the node is that the output of the LDO will also consequently be pulled high to reflect a similarly high value, typically Vcc.

FIG. 4 is a block diagram to show an exemplary embodiment for illustrating a more detailed configuration of the trimming control circuit 310 as that enclosed in the square block by the dotted lines. Under the condition when there are no signals specific to the trimming operations are injected through the input voltage pin 110, the ground pin 130 and the output pin 140, the device continue to operate under a normal operational condition. The test equipment 330 may monitor the output voltage generated from the output pin 140 to determine the changes of the operations of the circuit undergoing a trimming process. Meanwhile, as the trimming process is in progress, the input signals are inputted to the device under trimming via bypass pin 120 and EN pin 115. These input signals are used by the clocking logic circuit 450, the reset logic 460, and the fuse burn logic 410 of the trimming control circuit 310 coupled to the bypass pin 120 and the enable pin 115.

In this embodiment, the Bypass pin 120 is coupled to the respective logic blocks via an analog interface, 440. Most of the noises of the device are likely generated by the internal voltage reference, 160 of the regulator as shown in FIG. 1, a typical configuration is to bypass capacitor to the bypass line 120. The reference bypass capacitor filters the reference noise thus precluding an amplification of the noise by the error amplifier 170, and prevents further propagation of the noises to the output pin Vout 140.

Referring again to FIG. 4, for the purpose of trimming, the signal injected into the enable pin EN, 115 may be categorized as a clock to serially shift the counter register circuit 430. The signal injected through the Bypass pin 120 is used first to enable the trimming process. Then the signal inputted via the bypass pin 120 is applied to reset the counter register circuitry 430. Then, the signal is used to denote the fuse burning operations under a specified and determined condition according to a predefined trimming process. For the purpose of serially clocking the chosen bit for trimming, the clocking logic 450 controls the clocking signal injected into the counter register 430. The reset logic 460 resets the counter register 430. The counter register 430 is further coupled to a trimming transistor logic 420. The trimming transistor logic 420 controls the trimming of the selected bit based on a first fuse trim signal supplied by the counter register 430 and a second fuse trim signal supplied to it by the fuse burn logic circuit 410. In a preferred embodiment, the logic may be implemented as an AND logic of both signals. A chosen bit may be correspondingly trimmed from the appropriate selection of enable pin EN, 115, and Bypass pin 12 and, signals provided to the system via the test equipment 330 as that exemplified in FIG. 3.

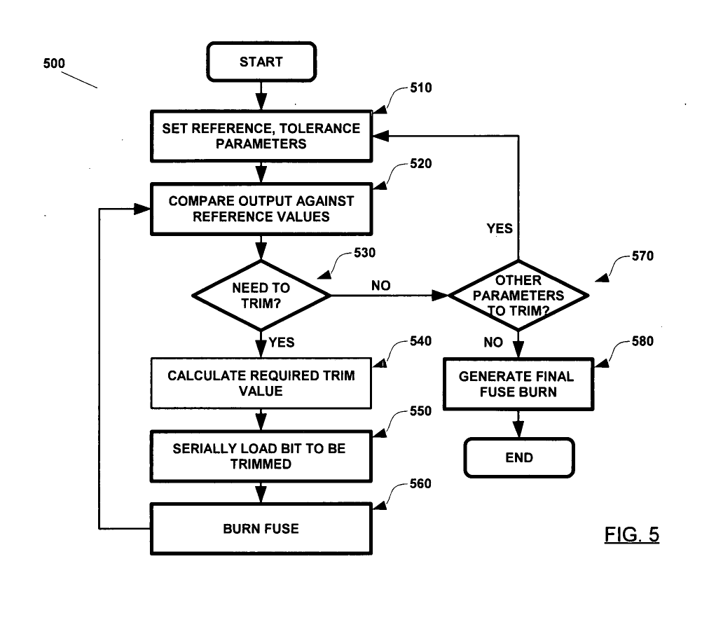

FIG. 5 illustrates an exemplary method to control the trimming procedure of a device by employing a trimming system as that shown in FIGS. 2 to 4. The method as shown in FIG. 5 is inherently iterative and dynamic in nature. The time requirement of a trimming operation is reduced because the method enables the completion of the trim process in a single loop. The system is dynamic in nature because there are no switches of the mode of operation of the core circuit. The device under trimming continuously maintains a normal operation and is fully function while the trimming process is in progress. Specifically, in response to the signals are inputted to the Bypass pin 120, the output pin Vout, 140 is pulled high to a voltage that is equivalent to the input voltage Vin pin 110 wherein the voltage on the input pin Vin, 110 constitutes an unregulated input voltage. Typically, the range of this input voltage exceeds that of the output voltage on the output pin Vout 140. Thus by selecting an appropriate voltage at the input pin Vin 110, it is possible to introduce a suitable voltage at an output pin Vout 140 particularly used only for the trimming sequence.

Referring to FIG. 5, the trimming procedure starts with the selection of appropriate reference and tolerance parameters (step 510) in the test equipment 330. The reference parameter is dependent on the number of parameters that requires to be trimmed as well as the accuracy and precision according to the tolerance requirements of their respective specifications. These preset values are compared against the output received from the output pin Vout 140 of the device to be trimmed under typical operating conditions (step 520). Based on the variation between the reference parameters and the output pin Vout 140, the values as well as the required tolerances, the test equipment 330 determines a trimming requirement according to the differences between the reference target values and the measured values from the output pin 140 (step 530).

In contrast to various prior art that implements multiple network bit selection at one time, the method disclosed by this invention is totally different. Specifically, the exemplary method as illustrated for performance on a test configuration shown above is inherently iterative because the system is trimmed one bit at a time. The first bit trimmed will be a rough trim for the purpose of making the difference between specified reference value in the test equipment 330 as close as possible to the output Vout 140. In certain cases, a deliberate error is introduced to avoid over-trimming of the system. The deliberate error introduced depends on whether the impedance network 180 is designed to account for increasing the impedance ratio, decreasing the impedance ratio, or for both increasing and decreasing the value of the impedance ratio. Once the bit to be trimmed is established (step 540), the corresponding bit is serially loaded (step 550) into the counter register 430 of the trimming control circuit 310. This single bit is thus trimmed accordingly (step 560).

Corresponding to the iterative nature of the exemplary embodiment of the present invention, subsequent bits will be trimmed one bit at a time, each time bringing the value of the output Vout 140 closer to the required reference value specified and preset in the test equipment 330. The extent of the trimming is dependent on the number of bits and impedance ladder of the impedance network 180 as well as the tolerance parameter specified in the test equipment 330.

When it can be established that the specified output parameter on the output pin Vout, 140 satisfies the requirements according to the specification, the system checks whether any other parameter requires trimming. The number of outputs that would require trimming as well as possible trimming of various other features internal to the system may include but not limited to the over-current trimming and over-temperature trimming as well as logic inversion of the enable line (step 570). Once it can be concluded that no further parameters require trimming, the system generates the final fuse burn to finalize the trimming procedure (step 580).

According to above descriptions and drawings, this invention discloses a circuit trimming system for carrying out an iterative and dynamic circuit trimming process. The circuit trimming system includes a test equipment 330 for providing input signals to a device under trimming (DUT) for maintaining a normal operation of the device under trimming to generate an output signal. The test equipment 330 further monitoring the output signal Vout 140 from the device under trimming for applying a trimming signal to a built-in trimming network 180 for trimming a predefined portion of the trimming network to further monitoring the output signals generated by the device under trimming in response to the trimming of the predefined portion of the trimming network. In the circuit trimming system, the device under trimming further includes a plurality of the predefined portions, e.g., circuit connected through 230. 231, 232, of the trimming network 180 each of the predefined portions further corresponding to a control signals quantifiable as a digital bit for carrying out a designated number of bits of trimming. In a preferred embodiment, the trimming network 180 further includes a plurality of predefined portions of impedance network, e.g., the impedance networks connected through 230.231, 232, wherein each portion further corresponding to a control signals quantifiable as a digital bit for carrying out a designated number of bits for trimming of a corresponding portion of the impedance network. Alternately, the trimming network 180 may further include a plurality of predefined portions of capacitance network (not specifically shown) wherein each portion further corresponding to a control signals quantifiable as a digital bit for carrying out a designated number of bits for trimming of a corresponding portion of the capacitance network. Alternately, the trimming network 180 may further include a plurality of predefined portions of inductance network (not specifically shown) wherein each portion further corresponding to a control signals quantifiable as a digital bit for carrying out a designated number of bits for trimming of a corresponding portion of the inductance network. Alternately, the trimming network 180 may further include a plurality of predefined portions of combined circuit network wherein the combined circuit network comprising impedance, capacitance and inductance (not specifically shown) wherein each portion further corresponding to a control signals quantifiable as a digital bit for carrying out a designated number of bits for trimming of a corresponding portion of the combined circuit network.

The test equipment 330 further monitors the output signals generated by the device under trimming in response to the trimming of the predefined portion of the trimming network to determine if the output signals fall outside of acceptable ranges according to a product specification for continuing another iteration of trimming of another predefined portion of the trimming network (as shown in FIG. 5). The test equipment 330 further monitors the output signals generated by the device under trimming in response to the trimming of the predefined portion of the trimming network to determine if the output signals fall within acceptable ranges according to a product specification for completing and terminating the iterative and dynamic circuit trimming process (as shown in FIG. 5).

The built-in trimming network 180 provides an anticipated total range of a trimming requirement for adjusting an output parameter of the DUT whereby no additional pin specific to a trimming operation is required other than existing pins of the DUT. In a preferred embodiment, the built-in trimming network 180 is coupled to a first set of switches, i.e., circuits connected through 230. 231, 232, each corresponding to switching on and off of one of the predefined portion of the trimming network wherein the switches are configured for trimming the predefined portion of the trimming network for adjusting the output signal according to a predefined curve whereby the DUT is trimmed substantially according to the predefined curve. The switches, i.e., circuits connected through 230. 231, 232, are configured for trimming the predefined portion of the trimming network for adjusting the output signal according to the predefined curve substantially of linear variation whereby the DUT is substantially linearly trimmed. In a preferred embodiment shown in FIG. 2, the switches further comprising transistors with gates connected together. More specifically, the switches are configured for trimming the predefined portion of the trimming network wherein the trimming network is divided into a first sub-network configured for trimming a denominator of a network characteristic value and a second sub-network configured for trimming a nominator of network characteristic value whereby the DUT is trimmed with adjustable ratios represented by the denominator network characteristic value and the nominator network characteristic value.

Alternately, as shown in FIG. 3, the built-in trimming network 180 are further coupled to a second set of switches for allowing additional flexibility of trimming the DUT. The switches are further configured to respond to a control signal quantifiable as a digital bit generated by the test equipment for carrying out a designated number of bits of trimming. The test equipment 330 generates and injects the input signal to the DUT as a series of periodic high and low pulses for shifting a counter register circuit in the test equipment for testing and trimming the DUT. In different embodiment, the test equipment 330 generates and injects the input signal to the DUT sequentially as a logic high pulse to enable a trimming process followed by a reset of a counter register 430 then completed with a negative edge signal for a fuse burning and trimming of the DUT. The test equipment 330 further comprises a clock logic circuit 450, a reset logic circuit 460, a fuse burning logic circuit 410, a counter register 430 and a trimming transistor logic 420 for monitoring and controlling the iterative and dynamic circuit trimming process.

The DUT includes an input pin Vin 110 coupled to the clock logic circuit 450 and the test equipment 330 further includes an analog interface circuit for coupling to the reset logic and fuse burn logic circuits 440 for compensating a signal inputted from the input pin for accentuating a logic characteristic of the signal injected from the input pin generated by the test equipment 330. The DUT includes two input pins with a first input pin 110 coupled to an input voltage and a second input pin 120 coupled to the clock logic circuit 450, the rest logic circuit 460 and the fuse burn logic circuit 410 with the first and second input pins coupled to an analog interface circuit 440. The DUT includes two input pins wherein one of the input pins is an enable pin 115 for the DUT and another of the input pin is a bypass pin 120 for bypassing the DUT.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

We claim:

1. A circuit trimming system for carrying out an iterative and dynamic circuit trimming process comprising:
a test equipment for providing input signals to a device under trimming (DUT) for maintaining a normal operation of said device under trimming to generate an output signal; and
said test equipment further monitoring said output signal from said device under trimming for applying a trimming signal to a built-in trimming network for trimming a predefined portion of said trimming network to further monitoring said output signals generated by said device under trimming in response to said trimming of said predefined portion of said trimming network.

2. The circuit trimming system of claim 1 wherein:
said device under trimming further include a plurality of said predefined portions of said trimming network each of said predefined portions further corresponding to a control signals quantifiable as a digital bit for carrying out a designated number of bits of trimming.

3. The circuit trimming system of claim 1 wherein:
said trimming network further includes a plurality of predefined portions of impedance network wherein each portion further corresponding to a control signals quantifiable as a digital bit for carrying out a designated number of bits for trimming of a corresponding portion of said impedance network.

4. The circuit trimming system of claim 1 wherein:
said trimming network further includes a plurality of predefined portions of capacitance network wherein each portion further corresponding to a control signals quantifiable as a digital bit for carrying out a designated number of bits for trimming of a corresponding portion of said capacitance network.

5. The circuit trimming system of claim 1 wherein:
said trimming network further includes a plurality of predefined portions of inductance network wherein each portion further corresponding to a control signals quantifiable as a digital bit for carrying out a designated number of bits for trimming of a corresponding portion of said inductance network.

6. The circuit trimming system of claim 1 wherein:
said trimming network further includes a plurality of predefined portions of combined circuit network wherein said combined circuit network comprising impedance, capacitance and inductance wherein each portion further corresponding to a control signals quantifiable as a digital bit for carrying out a designated number of bits for trimming of a corresponding portion of said combined circuit network.

7. The circuit trimming system of claim 1 wherein:
said test equipment further monitoring said output signals generated by said device under trimming in response to said trimming of said predefined portion of said trimming network to determine if said output signals fall outside of acceptable ranges according to a product specification for continuing another iteration of trimming of another predefined portion of said trimming network.

8. The circuit trimming system of claim 1 wherein:
said test equipment further monitoring said output signals generated by said device under trimming in response to said trimming of said predefined portion of said trimming network to determine if said output signals fall within acceptable ranges according to a product specification for completing and terminating said iterative and dynamic circuit trimming process.

9. The circuit trimming system of claim 1 wherein:
said built-in trimming network provides an anticipated total range of a trimming requirement for adjusting an output parameter of said DUT whereby no additional pin specific to a trimming operation is required other than existing pins of said DUT.

10. The circuit trimming system of claim 1 wherein:
said built-in trimming network are coupled to a first set of switches each corresponding to switching on and off of one of said predefined portion of said trimming network wherein said switches are configured for trimming said predefined portion of said trimming network for adjusting said output signal according to a predefined curve whereby said DUT is trimmed substantially according to said predefined curve.

11. The circuit trimming system of claim 10 wherein:
said switches are configured for trimming said predefined portion of said trimming network for adjusting said output signal according to said predefined curve substantially of linear variation whereby said DUT is substantially linearly trimmed.

12. The circuit trimming system of claim 10 wherein:
said switches further comprising transistors with gates connected together.

13. The circuit trimming system of claim 10 wherein:
said switches are configured for trimming said predefined portion of said trimming network wherein said trimming network is divided into a first sub-network configured for trimming a denominator of a network characteristic value and a second sub-network configured for trimming a nominator of network characteristic value whereby said DUT is trimmed with adjustable ratios represented by said denominator network characteristic value and said nominator network characteristic value.

14. The circuit trimming system of claim 11 wherein:
said built-in trimming network are further coupled to a second set of switches for allowing additional flexibility of trimming said DUT.

15. The circuit trimming system of claim 10 wherein:
said switches further configured to respond to a control signal quantifiable as a digital bit generated by said test equipment for carrying out a designated number of bits of trimming.

16. The circuit trimming system of claim 1 wherein:
said test equipment generates and injects said input signal to said DUT as a series of periodic high and low pulses for shifting a counter register circuit in said test equipment for testing and trimming said DUT.

17. The circuit trimming system of claim 1 wherein:
said test equipment generates and injects said input signal to said DUT sequentially as a logic high pulse to enable a trimming process followed by a reset of a counter register then completed with a negative edge signal for a fuse burning and trimming of said DUT.

18. The circuit trimming system of claim 1 wherein:
said test equipment further comprises a clock logic circuit, a reset logic circuit, a fuse burning logic circuit, a counter register and a trimming transistor logic for monitoring and controlling said iterative and dynamic circuit trimming process.

19. The circuit trimming system of claim 17 wherein:
said DUT includes an input pin coupled to said clock logic circuit and said test equipment further includes an analog interface circuit for coupling to said reset logic and fuse burn logic circuits for compensating a signal inputted from said input pin for accentuating a logic characteristic of said signal injected from said input pin generated by said test equipment.

20. The circuit trimming system of claim 17 wherein:
said DUT includes two input pins with a first input pin coupled to an input voltage and a second input pin coupled to said clock logic circuit, said rest logic circuit and said fuse burn logic circuit with said first and second input pins coupled to an analog interface circuit.

21. The circuit trimming system of claim 17 wherein:
said DUT includes two input pins with a first input pin coupled to an input voltage and a second input pin coupled to said clock logic circuit, said rest logic circuit and said fuse burn logic circuit with at least on of said first and second input pins coupled to an analog interface circuit.

22. The circuit trimming system of claim 17 wherein:
said DUT includes two input pins with a first input pin coupled to an input voltage and a second input pin coupled to said clock logic circuit, said rest logic circuit and said fuse burn logic circuit wherein said first and second input pins are decoupled from an analog interface circuit.

23. The circuit trimming system of claim 17 wherein:
said DUT includes two input pins wherein one of said input pin is an enable pin for said DUT and another of said input pin is a bypass pin for bypassing said DUT.

24. A method for carrying out an iterative and dynamic circuit trimming process on a device under trimming (DUT) circuit comprising:
presetting reference and tolerance parameters in a test equipment for generating input signals from said test equipment to said device under trimming (DUT) for maintaining a normal operation of said device under trimming to generate an output signal; and
monitoring said output signal from said device under trimming for applying a trimming signal to a built-in trimming network for trimming a predefined portion of said trimming network to further monitoring said output signals generated by said device under trimming in response to said trimming of said predefined portion of said trimming network.

25. The method of claim 23 further comprising:
monitoring and comparing said output signals generated by said DUT in response to said trimming of said predefined portion of said trimming network with said reference and tolerance parameters to determine if said output signals fall outside of acceptable ranges according to a product specification for continuing another iteration of trimming of another predefined portion of said trimming network.

26. The method of claim 23 further comprising:
monitoring and comparing said output signals generated by said DUT in response to said trimming of said predefined portion of said trimming network with said reference and tolerance parameters to determine if said output signals fall within acceptable ranges according to a product specification for completing and terminating said iterative and dynamic circuit trimming process.

27. The method of claim 23 further comprising:
configuring said built-in trimming network to provide an anticipated total range of a trimming requirement for adjusting an output parameter of said DUT whereby no additional pin specific to a trimming operation is required other than existing pins of said DUT.

28. The method of claim 23 further comprising:
generating from said test equipment control signals quantifiable as number of bits for trimming each of said predefined portions of said trimming network in said device under trimming corresponding to said number of bits of said control signals.

29. The method of claim 27 further comprising:
carrying out said iterative and dynamic circuit trimming processes sequentially at one bit in one iteration according to said control signals sent by said test equipment.

30. The method of claim 27 further comprising:
introducing a deliberate error for avoiding an over-trimming of said DUT.

31. The method of claim 27 further comprising:
conducting a high current in response to a control signals from said test equipment for destroying a circuit connection in carrying out said trimming process.

32. The method of claim 27 further comprising:
introducing an avalanche breakdown in a transistor nodes in response to a control signals from said test equipment in carrying out said trimming process.
